(19) United States
(12) Patent Application Publication
(10) Pub. No.: US 2019/0393064 A1
(43) Pub. Date: Dec. 26, 2019

(54) APPARATUS FOR ROUTING A CARRIER IN A PROCESSING SYSTEM, A SYSTEM FOR PROCESSING A SUBSTRATE ON THE CARRIER, AND METHOD OF ROUTING A CARRIER IN A VACUUM CHAMBER

(71) Applicant: Applied Materials, Inc., Santa Clara, CA (US)

(72) Inventors: Sebastian Gunther ZANG, Mainaschaff (DE); Oliver HEIMEL, Wabern (DE); Stefan BANGERT, Steinau (DE)

(21) Appl. No.: 15/765,159

(22) PCT Filed: Apr. 12, 2017
(86) PCT No.: PCT/EP2017/058827

§ 371 Date: Mar. 30, 2018

(30) Foreign Application Priority Data
Mar. 17, 2017 (EP) PCT/EP2017/056367

(51) Int. Cl. H01L 21/677

(52) U.S. Cl. CPC H01L 21/67715; H01L 21/67709; H01L 21/67721; H01L 21/67712; H01L 21/67739; H01L 21/6773

(57) ABSTRACT

An apparatus for routing a carrier in a processing system is described. The apparatus includes a first holding assembly attached to a vacuum chamber for transportation of the carrier along a first direction, a second holding assembly attached to the vacuum chamber for transportation of the carrier along a second direction different from the first direction, and a rotatable support for rotating the carrier from the first direction to the second direction.

### TECHNICAL FIELD

Embodiments of the present invention relate to routing a carrier in a processing system, for example in a rotation module. Embodiments of the present invention particularly relate to apparatus for routing a carrier in a processing system, a system for processing a substrate on the carrier, and method of protein carrier in a vacuum chamber.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc. for displaying information. OLEDs can also be used for general space illumination. The range of colors, brightness, and viewing angle possible with OLED displays is greater than that of traditional LCD displays because OLED pixels directly emit light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in a manner to form a matrix display panel having individually energizable pixels. The OLED is typically placed between two glass panels, and the edges of the glass panels are sealed to encapsulate the OLED therein. Alternatively, the OLED can be encapsulated with thin film technology, e.g. with a barrier film.

OLED display manufacturing has a plurality of challenges. Particle generation can deteriorate the manufacturing process. Accordingly, transportation of carriers in a processing system is beneficially provided with reduced or minimized particle generation. Further, contamination of devices, particularly of devices having OLED layers, can result in degradation of the devices such that the manufacture of a complete layer stack in a processing system and the encapsulation of the complete layer stack is beneficial. This results in large processing systems, for which the footprint of the system is to be considered. Accordingly, transportation of carriers in a vertical orientation can be beneficial. Rooting of carriers in the processing system in a vertical state can, for example, be accomplished with rotating modules. The rotating modules can be connected to two or more adjacent chambers, for example, four adjacent chambers, such that a carrier can be rotated for transportation in an arbitrary chamber of the adjacent chambers. The routing of the carriers is to be improved with consideration of at least one of particle generation, footprint, tact time, and also cost of ownership.

### SUMMARY

According to one embodiment, an apparatus for routing a carrier in a processing system is provided. The apparatus includes a first holding assembly attached to a vacuum chamber for transportation of the carrier along a first direction, a second holding assembly attached to the vacuum chamber for transportation of the carrier along a second direction different from the first direction, and a rotatable support for rotating the carrier from the first direction to the second direction.

According to another embodiment, an apparatus for routing a carrier in a processing system is provided. The apparatus includes a first holding assembly being stationary within a vacuum chamber for transportation along a first direction, a second holding assembly being at least partially stationary within the vacuum chamber for transportation along a second direction different from the first direction, and a rotatable support for rotating the carrier from the first direction to the second direction.

According to another embodiment, a system for processing a substrate on a carrier is provided. The system includes an apparatus for routing a carrier in a processing system. The apparatus includes a first holding assembly attached to a vacuum chamber for transportation of the carrier along a first direction, a second holding assembly attached to the vacuum chamber for transportation of the carrier along a second direction different from the first direction, and a rotatable support for rotating the carrier from the first direction to the second direction. The system further includes a processing chamber mounted to the vacuum chamber for transportation of the carrier into the processing chamber along the first direction.

According to another embodiment, a method of routing a carrier in a vacuum system is provided. The method includes transporting the carrier along a first direction in a vacuum chamber, placing the carrier on a rotatable support; rotating the rotatable support, and transporting the carrier along a second direction different from the first direction out of the vacuum chamber.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1 shows a schematic perspective view of a routing module of a processing system according to embodiments described herein;

FIG. 2 shows a schematic cross-sectional view of a routing module of a processing system according to embodiments described herein;

FIGS. 3A and 3B show schematic top views of a routing module of a processing system according to embodiments described herein;

FIG. 4 shows a schematic view of two neighboring routing modules each having a process module connected thereto according to embodiments described herein; and

FIG. 5 shows a flowchart illustrating methods of routing a carrier in a vacuum system according to embodiments described herein.

### DETAILED DESCRIPTION OF EMBODIMENTS

Reference will now be made in detail to the various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments of the present disclosure refer to routing of a carrier in a processing system. The processing system can be a display manufacturing system, particularly a display manufacturing system for large area substrates or carriers corresponding to large area substrates. The routing of carriers, i.e. the movement of the carriers through the system can inter alia be provided in an essentially vertical state of the carriers. For example, carriers can be configured to hold a mask for masking a substrate, such as a fine metal mask, or can be configured to hold a substrate, such as a glass plate.

According to some embodiments, which can be combined with other embodiments described herein, a substrate carrier can be an electrostatic chuck (E-chuck) providing an electrostatic force for holding the substrate and optionally the mask at the substrate carrier, and particularly at the support surface. As an example, the substrate carrier includes an electrode arrangement configured to provide an attracting force acting on the substrate.

According to some embodiments, which can be combined with other embodiments described herein, the carriers are configured for holding or supporting the substrate and the mask in a substantially vertical orientation. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carriers, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

The embodiments described herein can be utilized for evaporation on large area substrates, e.g., for OLED display manufacturing. Specifically, the substrates for which the structures and methods according to embodiments described herein are provided, are large area substrates. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

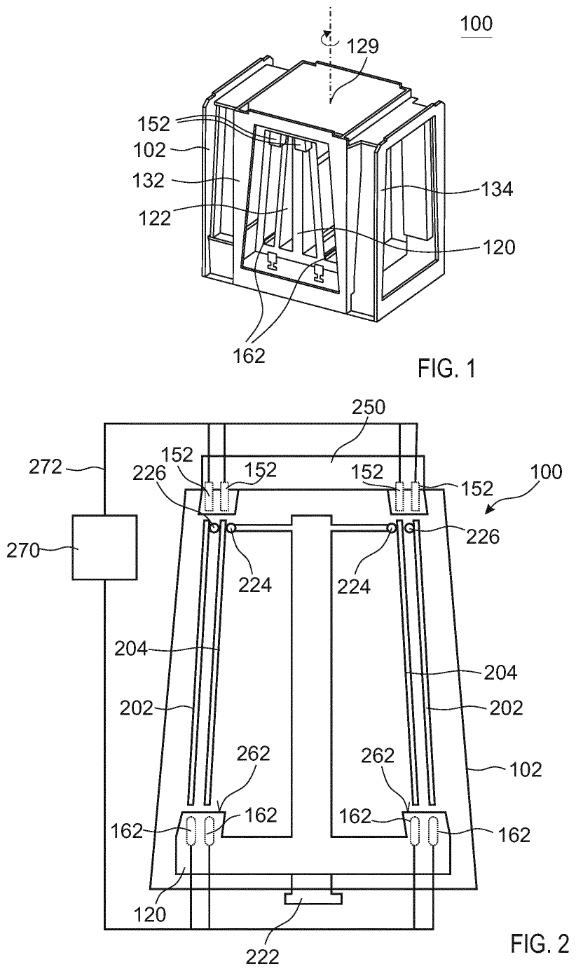

With exemplary reference to FIG. 1, embodiments of a routing module 100 for a processing system are described. In particular, a perspective view of a routing module 100 is shown in FIG. 1. As exemplarily shown in FIG. 1, typically the routing module 100 includes a rotation unit or rotatable support 120, which is configured to rotate the substrate carrier and/or the mask carrier such that the substrate carrier and/or the mask carrier can be transferred to a neighboring connected vacuum chamber, e.g. process module. In particular, the rotatable support 120 may be provided in a vacuum routing chamber 102, particularly a vacuum routing chamber which can be configured to provide vacuum conditions in the chamber. More specifically, the rotation unit may include a rotation drive configured for rotating a support structure 122 for supporting a substrate carrier and/or a mask carrier around a rotation axis 129. In particular, the rotation drive may be configured for providing a rotation of at least 180° of the rotation unit in a clockwise and/or an anti-clockwise direction. For example, the rotation drive may be configured for providing a rotation of 360°.

According to some embodiments, the rotatable support may include a pole, such as a center pole including a rotation axis. A first platform or a first assembly of two or more arms may be provided towards a lower end of the pole. The first platform or the first assembly of two or more arms may support the drive structure 162. The first platform may be in contact with a carrier during rotation and may support the weight of the carrier during rotation. A second platform or a second assembly of two or more arms may be provided towards an upper end of the pole. The second platform or the second assembly of two or more arms may support sideguides 224 and 226. The second platform or the second assembly of two or more arms may receive horizontal forces of carriers when carriers are positioned on the rotatable support.

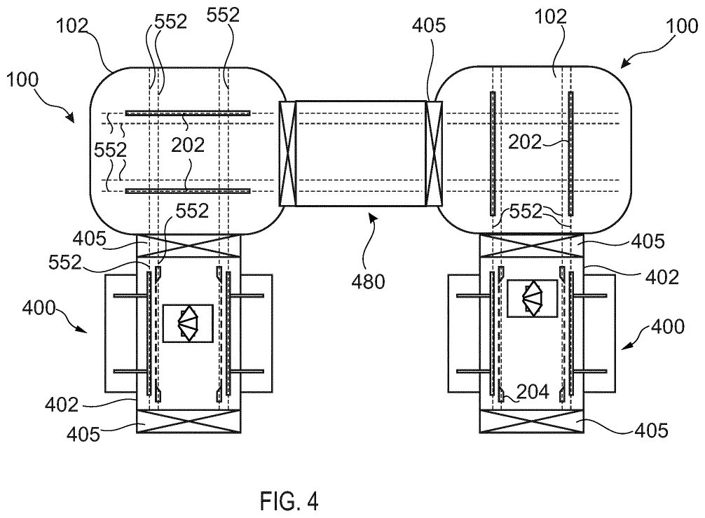

Further, as exemplarily shown in FIG. 1, the routing module 100 typically includes at least one first connecting flange 132 and at least one second connecting flange 134. For example, the at least one first connecting flange 132 may be configured for connecting a process module as described herein. The at least one second connecting flange 134 may be configured for connecting a transit module, a further routing module or a vacuum swing module, as exemplarily described with respect to FIG. 4. Typically, the routing module includes four connecting flanges, e.g. two first connecting flanges and two second connecting flanges, each pair of which being arranged on opposing sides of the routing module. Accordingly, the routing module may include two different types of connecting flanges, e.g. a connecting flange for connecting a process module, and a connecting flange for connecting a transit module, a field of routing module, or a swing module. Typically, some or all of the different types of connecting flanges have a casing frame-like structure which are configured for providing vacuum conditions inside the casing frame-like structure. Further, the connecting flanges may include an entrance/exit for the mask carrier and an entrance/exit for the substrate carrier.

As described with reference to FIG. 1, according to some embodiments, which can be combined with other embodiments described herein, one or more of the routing tracks may be included in a vacuum routing chamber 102 provided with a rotatable support 120. Therein, the substrate provided in a substrate carrier and/or the mask provided in a mask carrier employed during operation of the processing system can be rotated around a rotation axis 129, e.g. a vertical central axis.

Typically, the rotatable support 120 is configured for rotating a carrier from a first transportation track arrangement including a first holding assembly 152 to a second transportation track arrangement including a second holding assembly 152. Accordingly, the orientation of the carrier inside the routing module can be varied. In particular, the routing module may be configured such that the carrier can be rotated by at least 90°, for example by 90°, 180° or 360°, such that the carriers on the tracks are rotated in the position to be transferred in one of the adjacent chambers of the processing system.

According to embodiments of the present disclosure, which can be combined with other embodiments described herein, an apparatus for routing a carrier in a processing system is provided. The apparatus includes a first holding assembly attached to a vacuum chamber for transportation of the carrier along a first direction; a second holding assembly attached to the vacuum chamber for transportation of the carrier along a second direction different from the first direction; and a rotatable support for rotating the carrier from the first direction to the second direction.

A transportation track may include a holding assembly 152 and a drive structure 162, particularly configured for a contactless translation of a substrate carrier and/or a mask carrier. According to some embodiments, which can be combined with other embodiments described herein, a first transportation track can be configured to transport a substrate carrier and a second transportation track can be configured to transport the substrate carrier. Further, the third transportation track for a mask carrier and a fourth transportation track for another mask carrier can be provided.

According to embodiments of the present disclosure, a transportation track arrangement can be configured for levitation, i.e. contactless holding, of the carrier, and for contactless transportation. A holding assembly can be provided with magnetic elements, such as active magnetic elements, that are arranged above the carrier. The holding assembly can pull the carrier from above. The active magnetic elements can be controlled to provide a gap between the holding assembly and the carrier. Contactless holding is provided. A drive structure can be provided to provide a driving force for transporting the carrier along the transport direction. The drive structure can include further active magnetic elements providing a force on the carrier. Contactless driving can be provided.

According to embodiments of the present disclosure, which can be combined with other embodiments described herein, an apparatus for routing a carrier in a processing system is provided, wherein at least one of the first holding assembly and the second holding assembly can be configured for contactless transportation of the carrier. The first and/or second holding assembly can include a plurality of active magnetic elements for levitating the carrier. The active magnetic elements of the first holding assembly can be arranged in a row extending in the first direction, i.e. a transportation direction, of the transportation track assembly. The active magnetic elements of the second holding assembly can be arranged in a row extending in a second direction, i.e. a different transportation direction, of a further transportation track assembly.

According to one option, the holding assembly or the holding assemblies can be attached to the rotatable support. During rotation of the rotatable support a carrier can be rotated while being levitated (without mechanical contact) by a holding assembly. Due to the rotation of the rotatable support, the direction of transport of the transportation track arrangement is varied. The carrier can be transported in a different direction after the rotation, for example, in a direction angled by 90° as compared to the direction before the rotation. Such arrangement has the holding assembly attached to the rotatable support, wherein the holding assembly is provided within the vacuum routing chamber 102. The holding assembly can only be accessible from within the vacuum routing chamber, internal cabling at high cost of ownership is provided, and the rotatable support is a stiff and heavy structure to provide for such a design.

The routing module 100 shown in FIG. 2 has a vacuum routing chamber 102 and a rotatable support 120 provided in the vacuum routing chamber. The one or more holding assemblies are attached to the vacuum routing chamber 102. The one or more holding assemblies are, thus, stationary relative to the vacuum routing chamber. The one or more holding assemblies are stationary during rotation of the rotatable support. This provides the advantage of easier cabling of the holding assemblies and enables to have the rotatable support with a reduced stiffness and a less heavy design (weight reduction), which reduces cost of ownership. The reduced weight of the rotatable support 120 further allows for a smaller motor 222, i.e. a motor with reduced torque, to rotate the rotatable support. Cost of ownership is further reduced. Further, the height of the vacuum routing chamber 102 can be reduced, which results in further weight reduction and reduced cost of ownership.

According to some embodiments, which can be combined with other embodiments described herein, the rotatable support can be configured to be in mechanical contact with the carrier during rotation of the carrier. Further, additionally or alternatively, the routing module may further include at least a third holding assembly for contactless transportation along the first direction; and at least a fourth holding assembly for contactless transportation along the second direction.

FIG. 2 shows four holding assemblies 152 provided in a housing 250, i.e. an enclosure. The four holding assemblies serve for four tracks in a first direction. Another four holding assemblies can be provided for the second direction. According to some embodiments, which can be combined with other embodiments described herein, two or more holding assemblies can be provided in a housing 250 provided at the wall of the vacuum routing chamber 102. For example, the housing 250 and/or the two or more holding assemblies 152 can be provided at or attached to the top wall of the vacuum routing chamber. According to some embodiments, the holding assemblies, i.e. levitation boxes, can be mounted at the chamber ceiling. The housing 250 allows access to the holding assemblies from outside of the vacuum routing chamber 102. A vacuum provided in the vacuum routing chamber does not hinder access to the holding assemblies, for example, for maintenance purposes. The levitation boxes are accessible without opening the vacuum routing chamber. According to some embodiments, which can be combined with other embodiments described herein, at least a portion of the first and/or the second holding assembly may be provided outside of the vacuum chamber. For example, at least a portion of the first and/or the second holding assembly may be mounted at a top wall of the vacuum chamber.

According to some embodiments, a routing module 100 may provide four transportation track assemblies. For example, as shown in FIG. 2, two transportation track assemblies can be provided for substrate carriers 202 and two transportation track assemblies can be provided for mask carriers 204. Each of the transportation track assemblies can include a holding assembly 152 and a drive structure 162. For example, each of the transportation track assemblies can include two holding assemblies, one for a first direction and one for a second different direction, and a drive structure. The holding assemblies 152 are attached to the vacuum routing chamber 102. The holding assemblies are stationary while the rotatable support 120 rotates. The drive structures 162 are mounted on the rotatable support 120 and rotate together with the rotatable support while rotating the rotatable support, for example, for varying the direction of one or more carriers loaded on the rotatable support.

According to some embodiments, which can be combined with other embodiments described herein, a holding assembly for a mask carrier and a holding assembly for a substrate carrier can be provided at the same height or at the same position relative to the carrier in a plane of the carrier. Further, a drive structure for a mask carrier and a drive structure for a substrate carrier can be provided at the same height or at the same position relative to the carrier in a plane of the carrier. This may also allow for moving a mask carrier on a substrate transportation track and vice versa. An apparatus may include a first track assembly configured for transportation of a substrate carrier and including a first portion configured to support the substrate carrier at a first end of the substrate carrier and a second portion configured to support or drive the substrate carrier at a second end of the substrate carrier opposite the first end of the substrate. The apparatus may include a second track assembly configured for transportation of a mask carrier and including a further first portion configured to support the mask carrier at a first end of a mask carrier and a further second portion configured to support the mask carrier at a second end of the mask carrier opposite the first end of the mask. A first distance between the first portion and the second portion of the first track arrangement and a second distance between the further first portion and the further second portion of the second track arrangement are essentially the same. For example, the first portion and the further first portion are arranged in a first plane defined by a transport direction and another direction perpendicular to the first direction, and the second portion and the further second portion are arranged in a second plane defined by the transport direction and the other direction. For example, the first transport direction can be a horizontal direction and the other direction is another horizontal direction or a vertical direction. For vertical substrates, the second direction can be an essentially vertical direction. The mask carrier and the substrate carrier can be at the same transportation level.

For rotation of a carrier, the carrier is levitated by a holding assembly and the drive structure 162 moves the carrier in the vacuum routing chamber 102 along the transportation direction of the holding assembly. The controller 270 controls the levitation of the holding assembly 152 of the transportation track for the carrier. The controller 270 controls the translational movement of the carrier with the drive structure while the carrier is in the levitated state. The carrier is placed on the rotatable support to be in mechanical contact with the rotatable support, for example, with sideguides and/or a support surface 262 of the rotatable support. For example, the support surface can be provided above the drive structures 162. For placing the carrier on the rotatable support, the holding assembly is controlled by the controller 270 and releases the carrier. The carrier is transferred from the levitated state into a non-levitated state, in which the carrier is placed on the rotatable support.

FIG. 2 exemplarily shows four sideguides. Two sideguides 224 are provided for supporting a mask carrier 204. Two sideguides 226 are provided for supporting a substrate carrier 202. After the carrier is placed on the rotatable support, the rotatable support can rotate the one or more carriers in a new direction, for example by an angle of 45°, 90°, 135°, 180°, 225°, 270° 315°, or 360°. A rotation angle for a routing module 100, as exemplarily shown in FIG. 1, and having four connecting flanges can typically be 90°, 180°, 270°, or 360°. After rotation, for example by 90°, the carrier is moved to an adjacent chamber. The drive structure 162 has been rotated together with rotatable support. That is, the drive structure has not moved relative to the carrier and is positioned for further transportation of the carrier. According to some embodiments, which can be combined with other embodiments described herein, the rotatable support may include a guiding assembly, e.g. a sideguide, configured for supporting the carrier in a vertical orientation or an orientation deviating by less than 10° from a vertical direction.

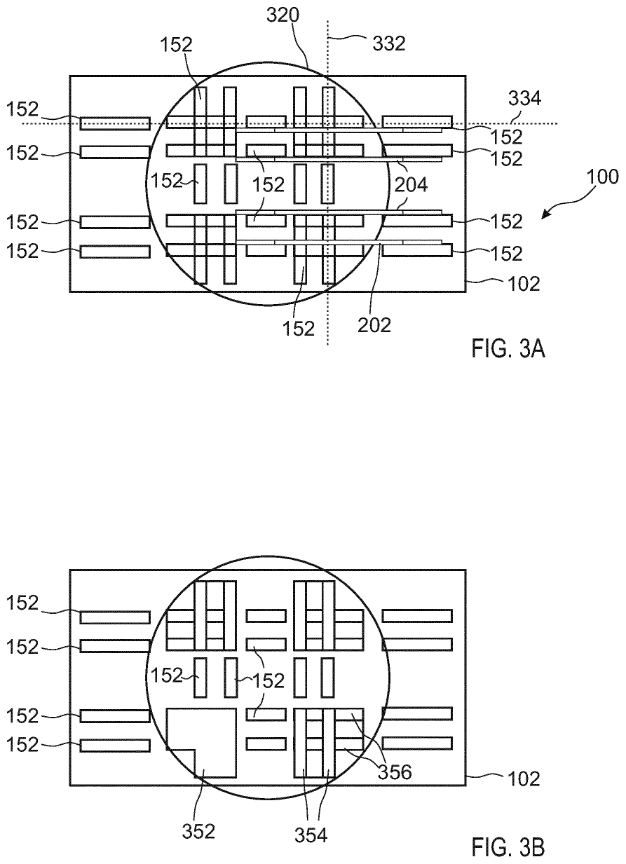

The holding assembly 152 of the previous transport direction (the transport direction before rotation, e.g. a first direction), which is stationary in the vacuum routing chamber, i.e. attached to the vacuum routing chamber, may not be suitable for levitation of the carrier in the new transport direction. Accordingly, according to embodiments, which can be combined with other embodiments described herein, a further holding assembly for a second, different direction of transportation is provided in the vacuum routing chamber 102. This is illustrated in more detail in FIGS. 3A and 3B. The further holding assembly can lift the carrier from the rotatable support. The drive structure can move the carrier in the second direction, which is different from the first direction, in a levitated state out of the vacuum routing chamber.

The routing module or the apparatus for routing a carrier in a processing system may further include a controller 270, as for example shown in FIG. 2. The routing module 100 or components thereof are coupled to the controller 270 by a communication cable 272. The controller 270 is operable to control routing of one or more carriers in the routing module. The controller 270 includes a programmable central processing unit (CPU) that is operable with a memory and a mass storage device, an input control unit, and/or a display unit (not shown), such as power supplies, clocks, cache, input/output (I/O) circuits, and the like, coupled to the various components of the routing module to facilitate control of the processes of handling and inspecting the substrates. The controller 270 may also include hardware for monitoring the routing of the carriers.

To facilitate control of the routing module 100 and routing of a carrier, the CPU may be one of any form of general-purpose computer processors for controlling the substrate process. The memory is coupled to the CPU and the memory is non-transitory and may be one or more of readily available memory such as random access memory (RAM), read only memory (ROM), floppy disk drive, hard disk, or any other form of digital storage, local or remote. Support circuits are coupled to the CPU for supporting the CPU in a conventional manner. The process for loading carriers by operation of the one or more transportation track assemblies and the rotatable support may be stored in the memory. The process for routing carriers may also be stored and/or executed by a second CPU (not shown) that is remotely located from the hardware being controlled by the CPU.

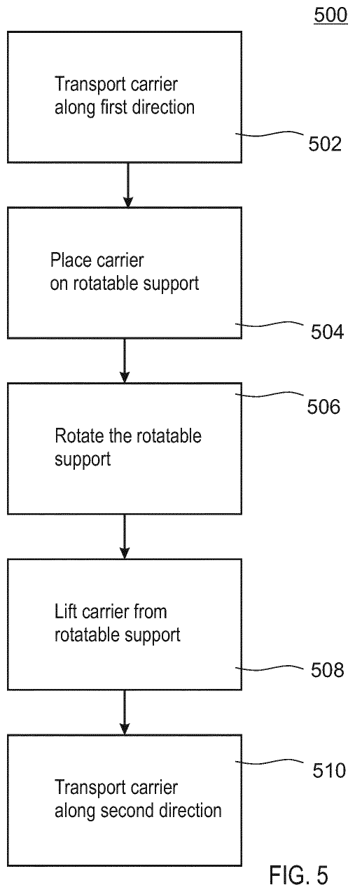

The memory is in the form of computer-readable storage media that contains instructions that, when executed by the CPU, facilitate the operation of the routing module as described in embodiments of the present disclosure. The instructions in the memory are in the form of a program product such as a program that implements the operation of the routing module 100, for example, the method 500 of FIG. 5, including for example the operation of routing of a carrier. The program code may conform to any one of a number of different programming languages.

FIG. 3A shows a routing module 100 having a vacuum routing chamber 102. In the top view of FIG. 3A, a routing module having four transportation track assemblies is shown. Other embodiments may include two, three, five, or six transportation track assemblies. An even number of transportation track assemblies is beneficial for routing concepts, in which empty carriers are routed on one or more of the tracks, on which carriers having substrates and masks supported on the carriers are also routed. In the event empty carriers are transported, i.e. routed, on a separate track, an uneven number of transportation track assemblies may also be beneficially provided.

FIG. 3A exemplarily shows two mask carriers 204 and two substrate carriers 202 provided on respective tracks, for example being levitated by respective transportation track assemblies. In the top view of FIG. 3A, holding assemblies 152 are illustrated. The holding assemblies are arranged for substrate transportation along a first direction 334 and a second direction 332, respectively. A first holding assembly, e.g. of a first transportation track assembly, having, for example, several levitation boxes, is attached to a vacuum chamber, for example, the vacuum routing chamber, for transportation of the carrier along the first direction 334. A second holding assembly, e.g. of the first transportation track assembly, having, for example, several levitation boxes, is attached to the vacuum chamber for transportation of the carrier along the second direction different from the first direction. As exemplarily shown in FIG. 3A, the first direction can be angled by 90° with respect to the second direction. Further, a routing module includes a rotatable support for rotating the carrier from the first direction to the second direction. The rotatable support is schematically illustrated by circle 320. According to embodiments of the present disclosure, which can be combined with other aspects and details to yield yet further embodiments, the first direction and the second direction can be considered a first transportation direction and a second transportation direction, respectively.

One or more of the substrate carriers 202 and/or one or more of the mask carriers 204 can be transported along the first direction 334 on a respective transportation track assembly on the rotatable support (see for example FIG. 2). Transportation of a carrier can be provided by operation of a drive structure, such as the drive box, wherein the carrier is magnetically levitated by a holding assembly and magnetically driven by the drive structure. FIG. 3A shows the carriers on the right-hand side such that the carriers would be transported from right to left on the rotatable support. It is possible that one carrier is transported from right to left on one transportation track, while another carrier is transported from left to right on another transportation track. After transportation of the one or more carriers over the rotatable support, the one or more carriers can be placed on the rotatable support, i.e. to rest on the rotatable support. In other words, the respective holding assembly is switched to a state in which the carrier is no longer levitated.

The rotatable support can rotate the carriers from the first direction 334 to, for example, the second direction 332. The levitation boxes providing the holding assembly for the second direction 332 are switched to the state, in which the carrier is levitated. The drive structure, such as drive boxes, can be operated to transport the one or more carriers along the second direction, for example, upwardly or downwardly in FIG. 3A. It is possible that one carrier is transported upwardly, while another carrier is transported downwardly, i.e. in an opposite direction.

As schematically shown in FIG. 3A, levitation boxes of the first holding assembly for the first direction and levitation boxes of the second holding assembly for the second direction may spatially interfere with each other. Accordingly, as shown in FIG. 3B, a routing module according to some embodiments of the present disclosure may include holding elements 352, such as levitation boxes, which enable transportation in the first direction and a second direction different from the first direction. Such holding elements 352 can be considered combined holding elements for the first holding assembly and the second holding assembly. A holding element 352 may include first active magnetic elements 356 for a first direction and second active magnetic elements 354 for a second direction. Accordingly, the first holding assembly may include a holding element 352 and the second holding assembly may include the same holding element 352.

In FIG. 4 a portion of a processing system is shown in which two process modules 400 are connected to each other via two routing modules 100. A first routing module 100 is connected to a first process module 400 and to a transit module 480, which is connected to a further routing module 100. The transit module provides a path along a transportation direction from the first routing module to the second routing module. Further, the transit module provides a parking position and a carrier on the two or more tracks, e.g. four transportation tracks 552, wherein a carrier can be moved out of one of the routing modules even though the other routing module is not yet in position to receive the carrier. As shown in FIG. 4, a transportation direction along the routing modules and/or the transit module may be a first direction. The transit module may provide a transportation path for the carrier when travelling along the first direction and may provide a parking position while carriers are oriented to be transported along the first direction.

The further routing module 100 is connected to a further process module 400. As shown in FIG. 4, a gate valve 405 can be provided between neighboring vacuum chambers along the first direction, for example, between the transit module and an adjacent routing module. The gate valve 405 can be closed or opened to provide a vacuum seal between the vacuum chambers. The existence of a gate valve may depend on the application of the processing system, e.g. on the kind, number, and/or sequence of layers of organic material deposited on a substrate. Accordingly, one or more gate valves can be provided between transfer chambers. Alternatively, no gate valve is provided between any of the transfer chambers.

According to typical embodiments, the first transportation track 552 and the second transportation track 552 are configured for contactless transportation of the substrate carrier and/or the mask carrier. In particular, the first transportation track and the second transportation track may include a holding assembly and a drive structure configured for a contactless translation of the substrate carrier and/or the mask carrier.

As illustrated in FIG. 4, in the first routing module 100, two substrates are rotated. The two transportation tracks, on which the substrates are located, are rotated to be aligned in the first direction. Accordingly, two substrates on the transportation tracks are provided in a position to be transferred to the transit module and the adjacent further routing module 100.

According to some embodiments, which can be combined with other embodiments described herein, the transportation tracks of the transportation track arrangement may extend from the vacuum process chamber 402 into a vacuum routing chamber 102, i.e. can be oriented in the second direction which is different from the first direction. Accordingly, one or more of the substrates can be transferred from a vacuum process chamber to an adjacent vacuum routing chamber. Further, as exemplarily shown in FIG. 4, a gate valve 405 may be provided between a process module and a routing module which can be opened for transportation of the one or more substrates. Accordingly, it is to be understood that a substrate can be transferred from the first process module to the first routing module, from the first routing module to the further routing module, and from the further routing module to a further process module. Accordingly, several processes, e.g. depositions of various layers of organic material on a substrate can be conducted without exposing the substrate to an undesired environment, such as an atmospheric environment or non-vacuum environment.

According to some embodiments, which can be combined with other embodiments described herein, a system for processing a substrate on a carrier can be provided. The system can include an apparatus for routing, i.e. a routing module according to embodiments of the present disclosure, and further include a processing chamber mounted to the vacuum chamber for transportation of the carrier into the processing chamber along the first direction. The system may further include a further vacuum chamber, e.g. a vacuum process chamber, mounted to the vacuum chamber for transportation of the carrier into the further vacuum chamber along the second direction. The system may further include a further vacuum chamber, e.g. a vacuum transit chamber, mounted to the vacuum chamber for transportation of the carrier into the yet further vacuum chamber along the first direction.

FIG. 5 illustrates a method 500 of routing a carrier in a vacuum system. The method includes transporting (box 502) the carrier along a first direction in a vacuum chamber, placing (box 504) the carrier on a rotatable support, rotating (box 506) the rotatable support, lifting (box 508) the carrier from the rotatable support, and transporting (box 510) the carrier along a second direction which is different from the first direction out of the vacuum chamber. For example, the transporting can be provided by a magnetic levitation system. Additionally or alternatively, the carrier can be lifted with a magnetic levitation system. According to some embodiments of the present disclosure, which can be combined with other embodiments described herein, the carrier can be supported in the vacuum chamber in a vertical orientation or an orientation deviating by less than 10° from a vertical direction.

The present disclosure has several advantages including being enabled to have the rotatable support with a reduced stiffness and a less heavy design (weight reduction), and the cabling of the holding assemblies being easier, which reduces cost of ownership. The mounting position of the holding assemblies allows access to the holding assemblies from outside of the vacuum routing chamber. Levitation boxes are accessible without opening the vacuum routing chamber.

While the foregoing is directed to some embodiments, other and further embodiments may be devised without departing from the basic scope, and the scope is determined by the claims that follow.

1. An apparatus for routing a carrier in a processing system, comprising:
a first holding assembly attached to a vacuum chamber for transportation of the carrier along a first direction;
a second holding assembly attached to the vacuum chamber for transportation of the carrier along a second direction different from the first direction; and
a rotatable support for rotating the carrier from the first direction to the second direction.

2. The apparatus according to claim 1, wherein at least one of the first holding assembly and the second holding assembly is configured for contactless transportation of the carrier.

3. The apparatus according to claim 2, wherein the first holding assembly comprises a plurality of active magnetic elements for levitating the carrier.

4. The apparatus according to claim 3, wherein the plurality of active magnetic elements are stationary in the vacuum chamber.

5. The apparatus according to claim 3, wherein the active magnetic elements are configured to pull the carrier from above and to provide a gap between the first holding assembly and the carrier.

6. The apparatus according to claim 1, wherein the second holding assembly comprises a plurality of active magnetic elements arranged in a row extending in the second direction.

7. The apparatus according to claim 1, wherein the rotatable support is configured to be in mechanical contact with the carrier during rotating of the carrier.

8. The apparatus according to claim 1, further comprising:
at least a third holding assembly for contactless transportation of a carrier along the first direction; and
at least a fourth holding assembly for contactless transportation of a carrier along the second direction.

9. The apparatus according to claim 8, wherein the first holding assembly, the second holding assembly, the third holding assembly, and the fourth holding assembly each comprise active magnetic elements arranged in a row.

10. The apparatus according to claim 1, wherein the rotatable support provides a guiding assembly or a side guide configured for supporting the carrier in a vertical orientation or an orientation deviating by less than 15° from a vertical direction.

11. The apparatus according to claim 1, wherein at least a portion of the first holding assembly is located outside of the vacuum chamber.

12. The apparatus according to claim 11, wherein the portion of the first holding assembly is mounted at a top wall of the vacuum chamber.

13. A system for processing a substrate on a carrier, comprising:
a first holding assembly attached to a vacuum chamber for transportation of the carrier along a first direction;
a second holding assembly attached to the vacuum chamber for transportation of the carrier along a second direction different from the first direction;
a rotatable support for rotating the carrier from the first direction to the second direction, and
a processing chamber mounted to the vacuum chamber for transportation of the carrier into the processing chamber along the first direction.

14. The system according to claim 13, further comprising:
a further vacuum chamber mounted to the vacuum chamber for transportation of the carrier into the further vacuum chamber along the second direction.

15. A method of routing a carrier in a vacuum system, comprising:
transporting the carrier along a first direction in a vacuum chamber;
placing the carrier on a rotatable support;
rotating the rotatable support; and
transporting the carrier along a second direction different from the first direction out of the vacuum chamber.

16. The method according to claim 15, further comprising:
lifting the carrier from the rotatable support before transporting the carrier along the second direction.

17. The method according to claim 16, wherein the carrier is lifted with a magnetic levitation system.

18. The method according to claim 15, wherein the transporting is provided by a magnetic levitation system.

19. The method according to claim 15, wherein the carrier is supported in the vacuum chamber in a vertical orientation or an orientation deviating by less than 15° from a vertical direction.
